(19) United States
(12) Patent Application Publication
(10) Pub. No.: US 2007/0241331 A1
(43) Pub. Date: Oct. 18, 2007

(54) ELECTROLUMINESCENT DEVICE AND METHODS FOR FABRICATING THE SAME

(75) Inventors: Hsin-Hung Lee, Hsinchu (TW); Yun-Sheng Chen, Hsinchu (TW); Ming-Chang Shih, Hsinchu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu (TW)

(21) Appl. No.: 11/564,938

(22) Filed: Nov. 30, 2006

(30) Foreign Application Priority Data
Apr. 12, 2006 (TW) 95112991

(51) Int. Cl. H01L 29/04

(52) U.S. Cl. 257/59

(57) ABSTRACT

Electroluminescent devices and methods for fabricating the same are provided. An exemplary embodiment of an electroluminescent device comprises a substrate. A thin film transistor (TFT) is formed on the substrate. An insulating layer is formed to overlie the TFT and the substrate. An opening is formed in the insulating layer, exposing a source/drain region of the TFT. A conductive layer is formed over a portion of the insulating layer, filling the opening. A protection layer is formed overlying a portion of the insulating layer and the conductive layer. A light-emitting layer is formed overlying a portion of the conductive layer not covered by the protection layer. A top electrode is formed to overlie the light-emitting layer.

### BACKGROUND OF THE INVENTION

1. Field of the Invention

The invention relates to electroluminescent device fabrication, and in particular to an electroluminescent device and a method for fabricating the same.

2. Description of the Related Art

Current flat panel fabrication techniques yield organic electroluminescent displays with advantages of self-luminescence, wide-viewing angle, thin profile, light weight, low driving voltage and simple manufacturing process. In electroluminescent displays with a laminated structure, organic compounds such as dyes, polymers, or other luminescent materials serve as the organic luminescent layer and are disposed between a top electrode and a bottom electrode.

Organic electroluminescent displays can be classified into passive matrix and active matrix types depending on the driving mode. Passive matrix (PM) organic electroluminescent displays have advantages of a simple structure which reduces the number of fabrication processes and costs, but has the disadvantages of poor display quality for large size, high resolution images. Active matrix (AM) organic electroluminescent displays are driven by electric currents, in which each of the matrix-array pixel regions has at least one thin film transistor (TFT), serving as a switch, to modulate the driving current based on the variation in capacitor storage potential to thus control the brightness and gray level of the pixel regions. Therefore, the active matrix type organic electroluminescent display has the advantages of an increased number of scan lines, thereby achieving adequate display of large size, high resolution images.

At present, AM organic electroluminescent displays are driven by two TFTs in each pixel region, and, alternatively, by four TFTs in each pixel region. The utilized TFTs can be P type TFT, N type TFT, or combinations thereof. FIGS. 1a-1i are a series of cross sections illustrating a conventional method for fabricating an AM organic electroluminescent display. In this method, fabrication of a P-type TFT and an N-type TFT of the AM organic electroluminescent display are simultaneously illustrated.

As shown in FIG. 1a, a transparent substrate 100, for example a glass substrate, is first provided. Isolated device regions A and B are defined and provided over the transparent substrate 100, wherein the region A is a region for forming a P-type TFT and the region B is a region for forming an N-type TFT. An active layer 102, for example a polysilicon layer, is then formed over the transparent substrate 100 and patterned by sequential photolithography and etching processes (neither process is shown) through the use of a first reticle (not shown) having predetermined patterns thereon. Thus, a patterned active layer 102 is respectively formed over the transparent substrate 100 in regions A and B.

As shown in FIG. 1b, a photoresist layer (not shown) is next blanketly formed over the structure illustrated in FIG. 1a and then patterned by sequential photolithography and development processes (neither process is shown) through the use of a second reticle (not shown) having predetermined patterns thereon, thereby respectively forming a patterned photoresist layer 104 in regions A and B. Herein, the photoresist layer 104 formed in the region A substantially covers the entire surface of the active layer 102 therein and the photoresist layer 104 formed in the region B partially covers a surface of the active layer 102 therein. Next, an ion implantation process (not shown) is performed, incorporating N-type ions such as arsenic or phosphorus and using the photoresist layers 104 as implant masks, thereby forming a pair of source/regions 102a in portions of the active layer 102 not covered by the photoresist layer 104 in the region B and a channel region 102b formed between the source/regions 102a.

As shown in FIG. 1c, a dielectric layer 106 is next blanketly formed over the transparent substrate 100 illustrated in FIG. 1b after removal of the photoresist layers 104 thereon. The dielectric layer 106 can be, for example, a silicon dioxide layer covering the active layers 102 formed on the transparent substrate 100. A photoresist layer (not shown) is next blanketly formed over the dielectric layer 106 and patterned by sequential photolithography and development processes (neither process is shown) through the use of a third reticle (not shown) having predetermined patterns thereon, thereby forming two patterned photoresist layers 108 in regions A and B, respectively, wherein the resist layer 108 formed in the region A entirely covers the underlying active layer 102 and the resist layer 108 formed in region B partially covers the underlying active layer 102, thereby exposing a portion of the channel region 102b. Next, an ion implantation process (not shown) is performed, incorporating N-type ions such as arsenic or phosphorus and using the photoresist layers 108 as implant masks, thereby forming a pair of lightly doped source/regions 102c adjacent to the source/drain regions 102a in the active layer 102 in the region B. Doping concentrations in the lightly doped source/regions 102c are lower than that in the source/regions 102a.

As shown in FIG. 1d, after removal of the resist layer 108 illustrated in FIG. 1c, a photoresist layer (not shown) is next blanketly formed over the dielectric layer 106 and patterned by sequential photolithography and etching processes (neither process is shown) through the use of a fourth reticle (not shown) having predetermined patterns thereon, thereby forming two patterned photoresist layers 110 in regions A and B, respectively. As shown in FIG. 1d, the resist layer 110 in region B entirely covers the underlying active layer 102 and the resist layer 110 in region A partially covers the underlying active layer 102. Next, an ion implantation process is performed, incorporating P-type ions such as boron and using the photoresist layers 100 as implant masks, thereby forming a pair of doped source/regions 102d in the active layer 102 not covered by the photoresist layer 110 in region A, thereby defining a channel region 102e formed therebetween.

As shown in FIG. 1e, after removal of the resist layers 110 illustrated in FIG. 1d, a metal layer 112 is blanketly formed over the transparent substrate 100. The metal layer 112 may comprise W, Mo or combinations thereof. The metal layer 112 is then patterned by sequential photolithography and etching processes (neither process is shown) through the use of a fifth reticle (not shown) having predetermined patterns thereon, thereby forming two patterned metal layers 110 in regions A and B, respectively, wherein the metal layers 110 substantially overlie one of the channel regions 102e and 102b in regions A and B, respectively. At this point, a P-type TFT and an N-type TFT are substantially formed over the transparent substrate 100 in regions A and B, respectively.

As shown in FIG. 1f, an inter-layer dielectric layer is then blanketly formed over the transparent substrate 100 and patterned by sequential photolithography and etching processes (neither process is shown) through the use of a sixth reticle (not shown) having predetermined patterns thereon, thereby forming two openings OP in each of the regions A and B, respectively passing through the inter-layer dielectric layer 114 and the dielectric layer 106 to expose the source/drain regions 102d, 102a in regions A and B.

As shown in FIG. 1g, another metal layer is next formed over the transparent substrate 100 and fills the openings OP. Next, the metal layer is patterned by sequential photolithography and etching processes (neither process is shown) through the use of a seventh reticle (not shown) having predetermined patterns thereon, thereby forming a patterned metal layer 116 in each of the regions A and B, respectively. The patterned metal layer 116 connects one of the source/drain regions 102d, 102a in regions A and B thereunder.

In FIG. 1h, a planarization layer 118 is blanketly formed over the transparent substrate 100 and then patterned by sequential photolithography and etching processes (neither process is shown) through the use of an eighth reticle (not shown) having predetermined patterns thereon, thereby forming an opening OP′ in the planarization layer 118 in the region A and exposing the metal layer 114 in region A.

As shown in FIG. 1i, a conductive layer is then formed over the planarization layer 118 and fills the opening OP′. The conductive layer is next patterned by sequential photolithography and etching processes (neither process is shown) through the use of a ninth reticle (not shown) having predetermined patterns thereon, thereby forming a patterned conductive layer 120 in the region A. The conductive layer 120 and the underlying conductive layer 114 form a conductive path toward the underlying TFT. Next, a cap layer 112 is formed and patterned by sequential photolithography and etching processes (neither process is shown) through the use of a tenth reticle (not shown) having predetermined patterns thereon, thereby partially exposing the conductive layer 120. An organic light-emitting layer and a conductive layer can be sequentially formed over the conductive layer 120 to form an AM organic electroluminescent device.

Through illustrations of the above figures, fabrication of a TFT in such device requires uses of four to five reticles and fabrication of the electroluminescent device requires uses of ten reticles. Thus, the fabrication is excessively time consuming and expensive and throughput suffers.

Therefore, an electroluminescent device with reduced production cost and as simplified fabrication process is desirable.

### BRIEF SUMMARY OF THE INVENTION

Electroluminescent devices and methods for fabricating the same are provided. An exemplary embodiment of an electroluminescent device comprises a substrate. A thin film transistor (TFT) is formed on the substrate. An insulating layer is formed overlying the TFT. An opening is formed in the insulating layer, exposing a source/drain region of the TFT. A conductive layer is formed over a portion of the insulating layer, filling the opening. A protection layer is formed overlying a portion of the insulating layer and the conductive layer. A light-emitting layer is formed overlying a portion of the conductive layer not covered by the protection layer. A top electrode is formed overlying the light-emitting layer.

Another exemplary embodiment of an electroluminescent device comprises a substrate. A thin film transistor (TFT) is formed on the substrate. An layer is formed overlying the TFT and the substrate. An opening is formed in the insulating layer, exposing a source/drain region of the TFT. A transparent conductive layer is conformably formed over the insulating layer and in the opening. An opaque conductive layer is formed overlying a portion of the transparent conductive layer. A protection layer is formed overlying the opaque conductive layer and the transparent conductive layer, exposing a portion of the transparent conductive layer. A light-emitting layer is formed overlying the portion of the transparent conductive layer exposed by the protection layer. A top electrode is formed overlying the light-emitting layer.

An exemplary embodiment of a method for fabricating an electroluminescent device comprises providing a substrate. A first thin film transistor (TFT) and a second thin film transistor (TFT) are formed on the substrate, wherein the first and second TFTs comprise different conductivities, respectively. An insulating layer is formed to cover the first and second TFTs and the substrate. A plurality of openings are formed in the insulating layer, respectively exposing a pair of source/drain regions of the first and second TFTs. A conductive layer is formed over a portion of the insulating layer, filling the openings and covering portions of the insulating layer adjacent thereto. A protection layer is formed over the conductive layer, exposing a portion of the conductive layer adjacent to the first TFT. A light-emitting layer is formed over the protection layer and the portion of the conductive layer exposed by the protection layer. A top electrode is formed overlying the light-emitting layer.

Another exemplary embodiment of a method for fabricating an electroluminescent device comprises providing a substrate. A thin film transistor (TFT) is formed on the substrate. An insulating layer is formed to cover the TFTs and the substrate. A plurality of openings are formed in the insulating layer, respectively exposing a pair of source/drain regions of the TFT. A conductive layer is formed over a portion of the insulating layer, filling the openings and covering portions of the insulating layer adjacent thereto. A protection layer is formed over the conductive layer, exposing a portion of the conductive layer adjacent to the TFT. A light-emitting layer is formed over the portion of the conductive layer exposed by the protection layer. A top electrode is formed overlying the light-emitting layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a-1i are cross sections illustrating a conventional method for fabricating an electroluminescent device;

FIG. 2 is a schematic top view showing an electroluminescent device according to an embodiment of the invention;

FIGS. 3a-3h are cross sections taken along line 3-3 in FIG. 2, showing a method for fabricating a portion of the electroluminescent device according to a first embodiment of the invention;

FIGS. 4a-4h are cross sections taken along line 4-4 in FIG. 2, showing a method for fabricating another portion of the electroluminescent device according to the first embodiment of the invention;

FIG. 4i is a schematic view showing an electroluminescent device according to another embodiment of the invention;

FIGS. 5a-5b are cross sections taken along line 3-3 of FIG. 2, showing a method for fabricating a portion of the electroluminescent device according to a second embodiment of the invention; and

FIGS. 6a-6b are cross sections taken along line 4-4 of FIG. 2, showing a method for fabricating another portion of the electroluminescent device according to the second embodiment of the invention.

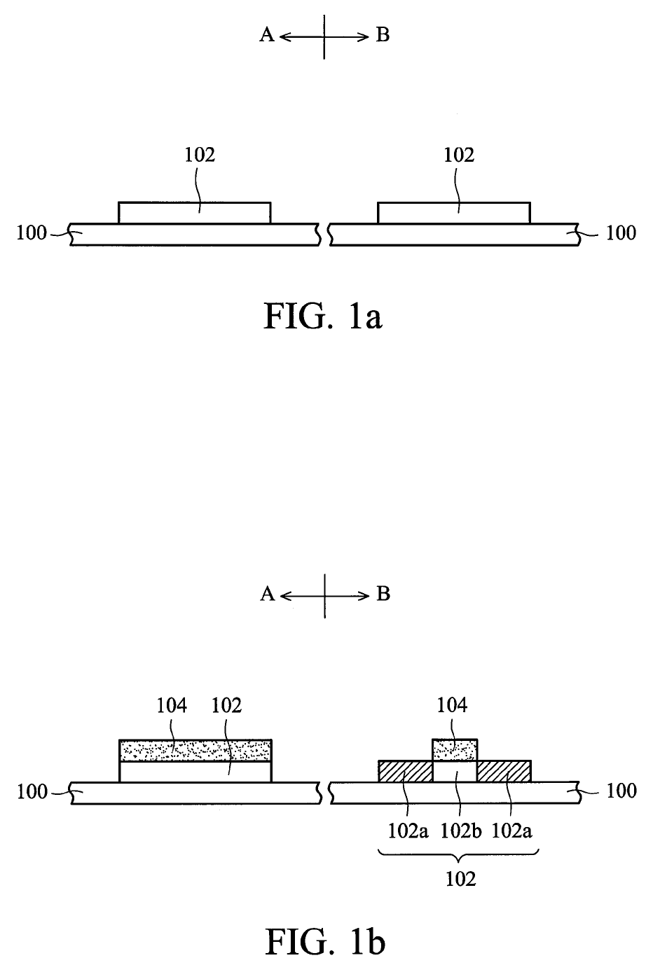

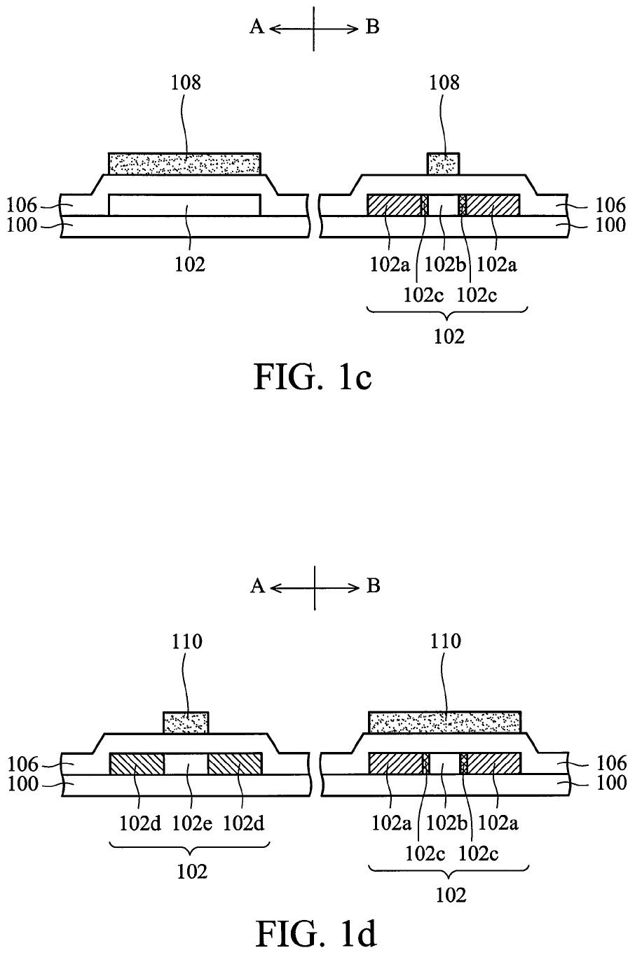

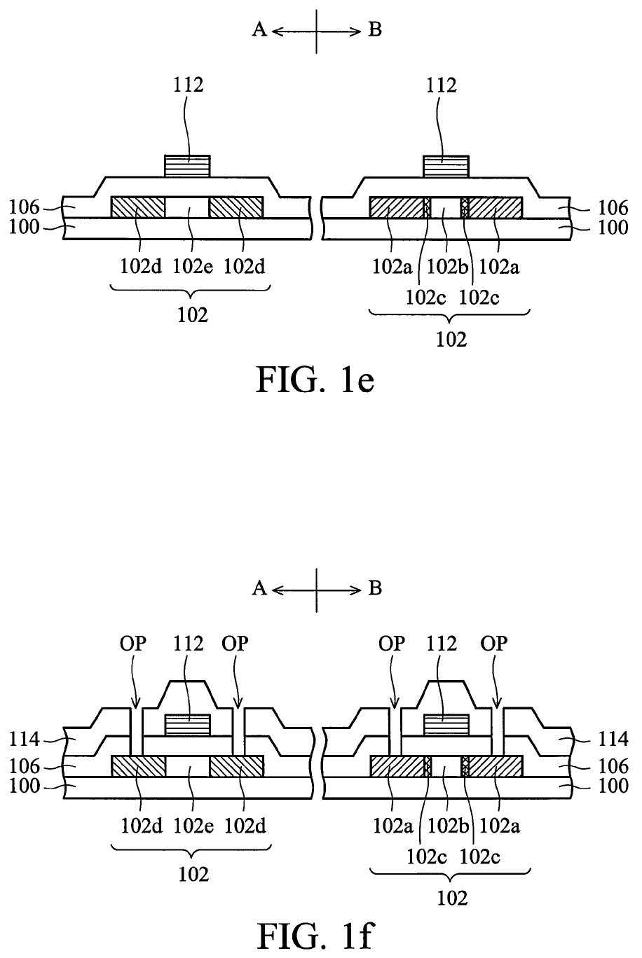

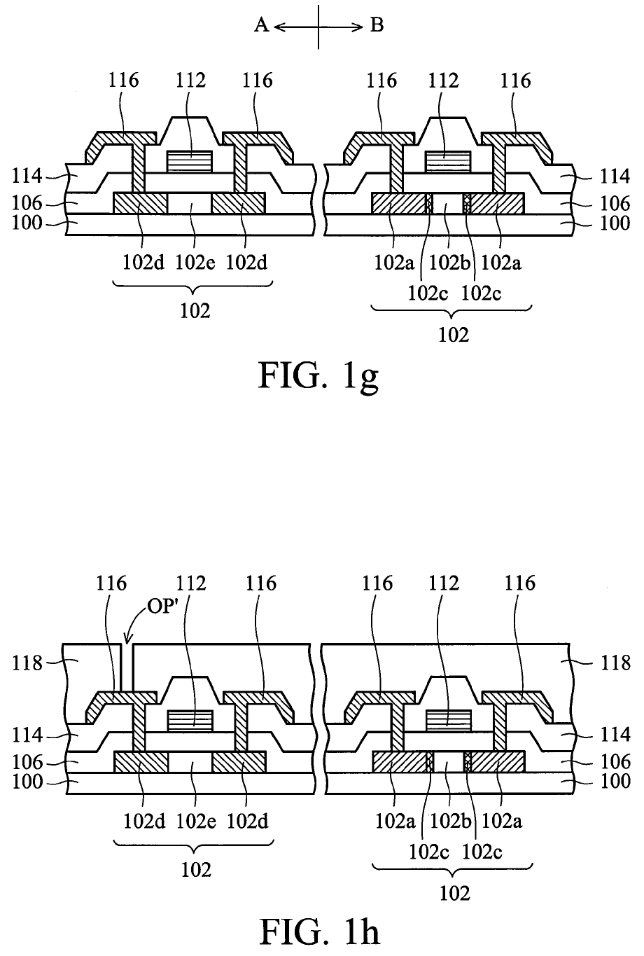

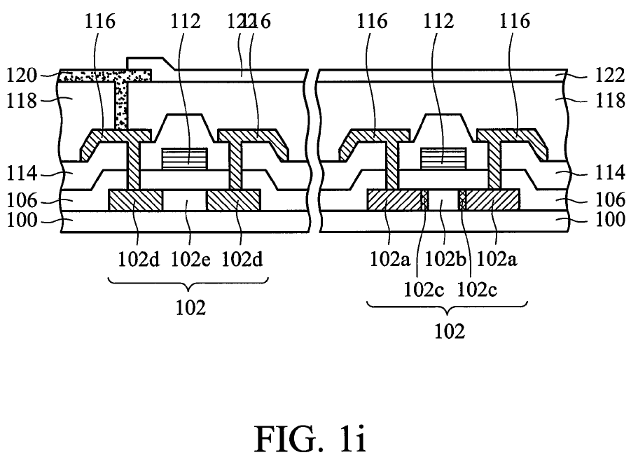

### DETAILED DESCRIPTION OF THE INVENTION

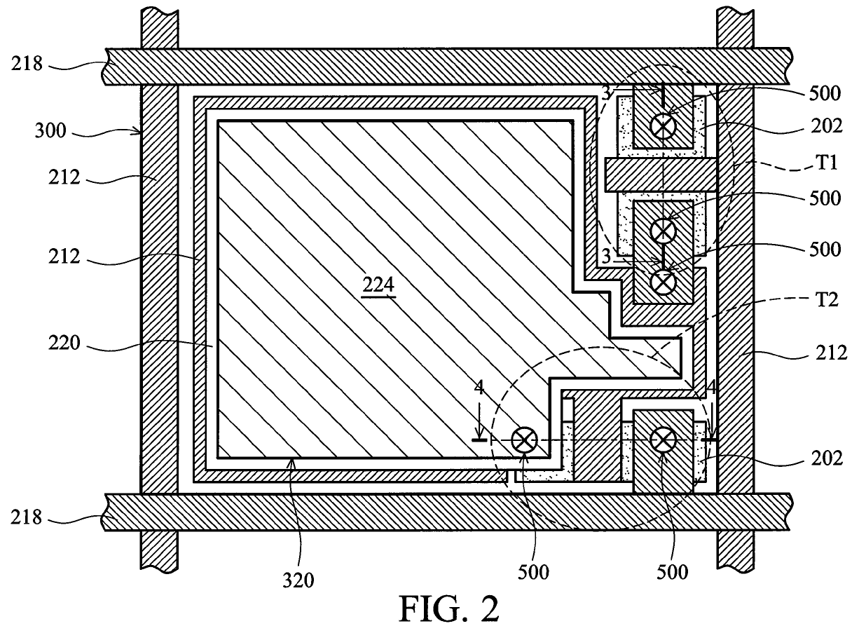

FIG. 2 shows a schematic top view showing portions of a display element of an AM electroluminescent display having pixel array according to an exemplary embodiment of the invention. As shown in FIG. 2, a display element 300 is provided, comprising two isolated device regions T1 and T2, and a display region 320. In the device region T1, an untitled thin film transistor (TFT) such as an N-type TFT, is provided and in the device region T2, an untitled TFT such as a P-type TFT, is provided and connects the display region 320. The display element 300 is defined by a plurality of intersecting conductive lines 212 and 218, wherein the conductive lines 212 function as scan lines, the upper conductive line 218 functions as a data line and the lower conductive line 218 functions as a power line here, for illustrations. One of the conductive lines 212 electrically connects the TFT in the region T1 and a source/drain region thereof is electrically connected with the upper conductive lines 218 by a contact (not shown). In region T2, another TFT electrically connects the display region 320 and the lower conductive lines 218 through a contact structure 500. The TFT in the region T2 functions as a switch during pixel scanning and provides continuous current to the devices in the display region 320.

In the following exemplary embodiments, electroluminescent devices and methods for fabricating the same are provided. Compared with conventional electroluminescent devices, the electroluminescent device of the invention can be formed with reduced cost and fewer fabrication steps, thereby improving electroluminescent devices fabrication efficiency.

Processes for fabricating electroluminescent devices in accordance with the invention are respectively illustrated in the following embodiments.

### First Embodiment

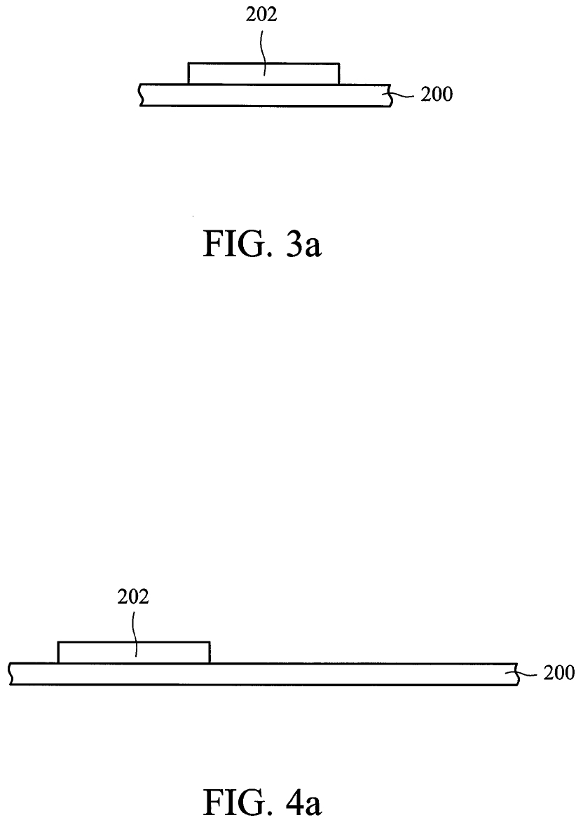

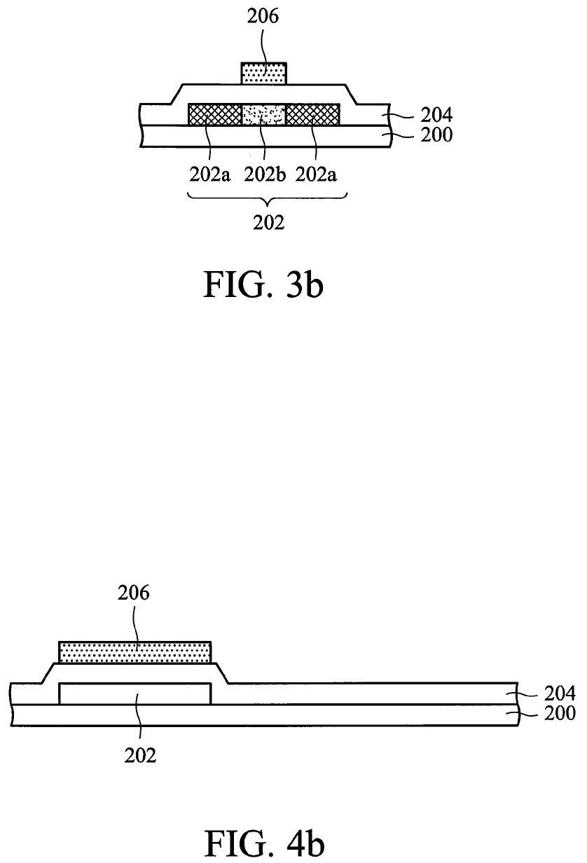

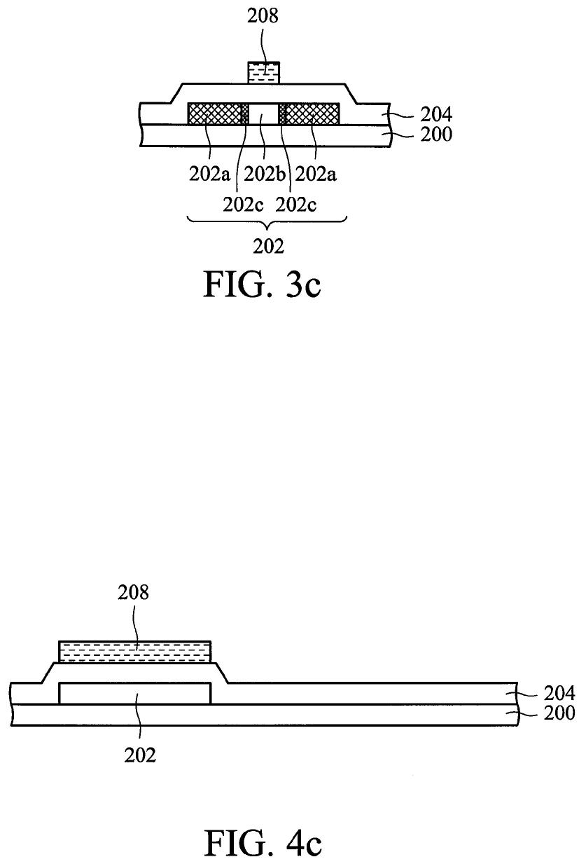

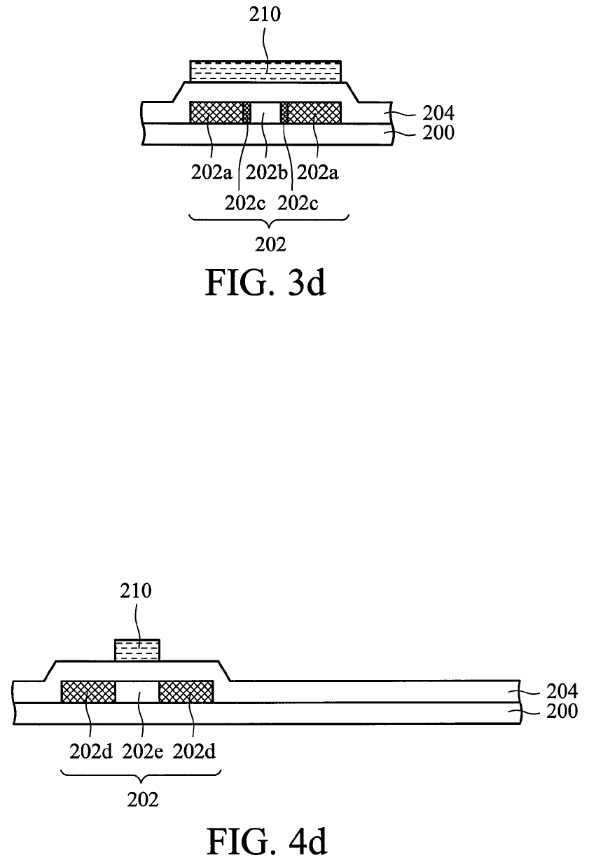

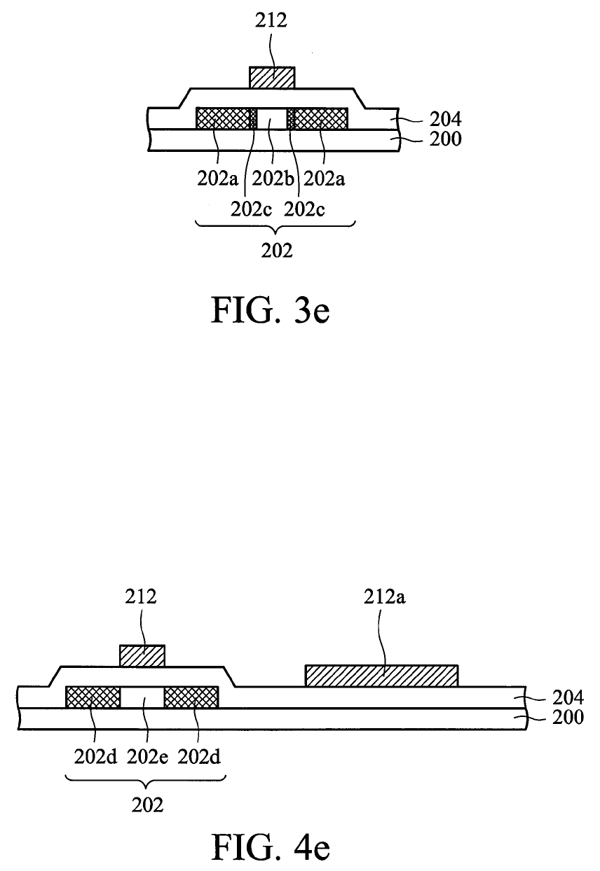

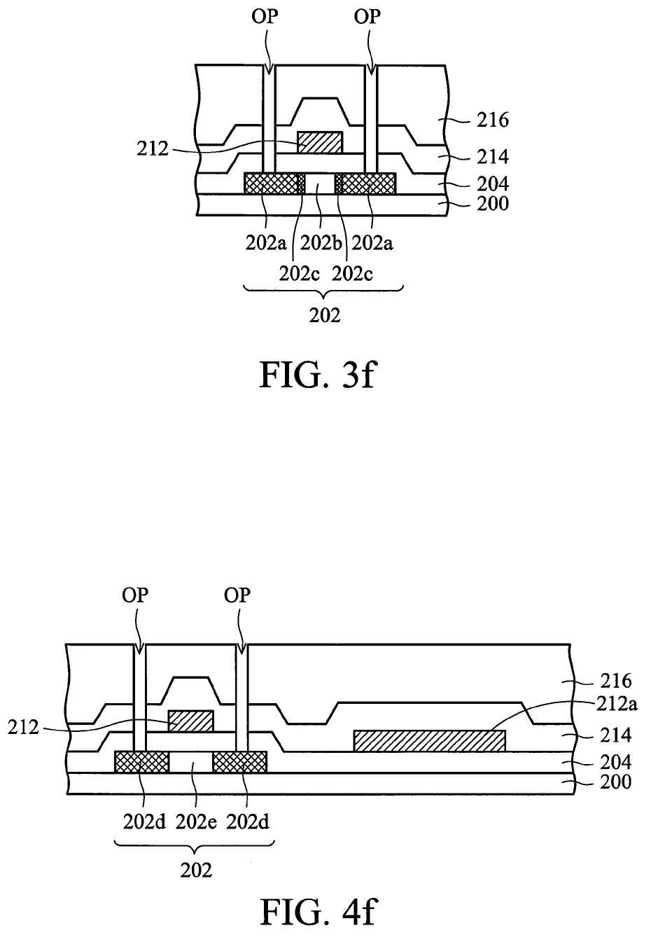

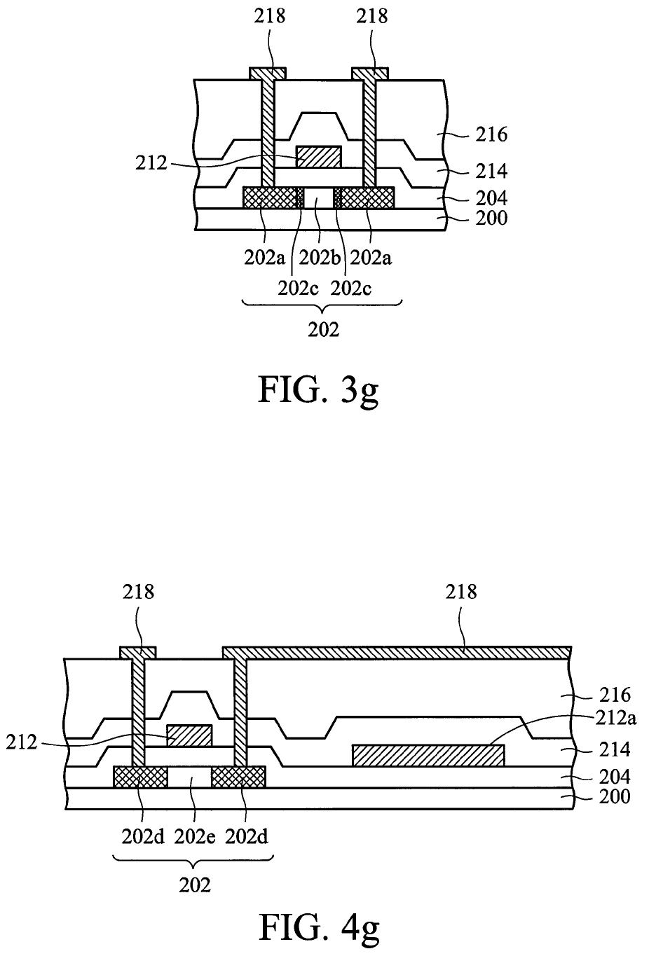

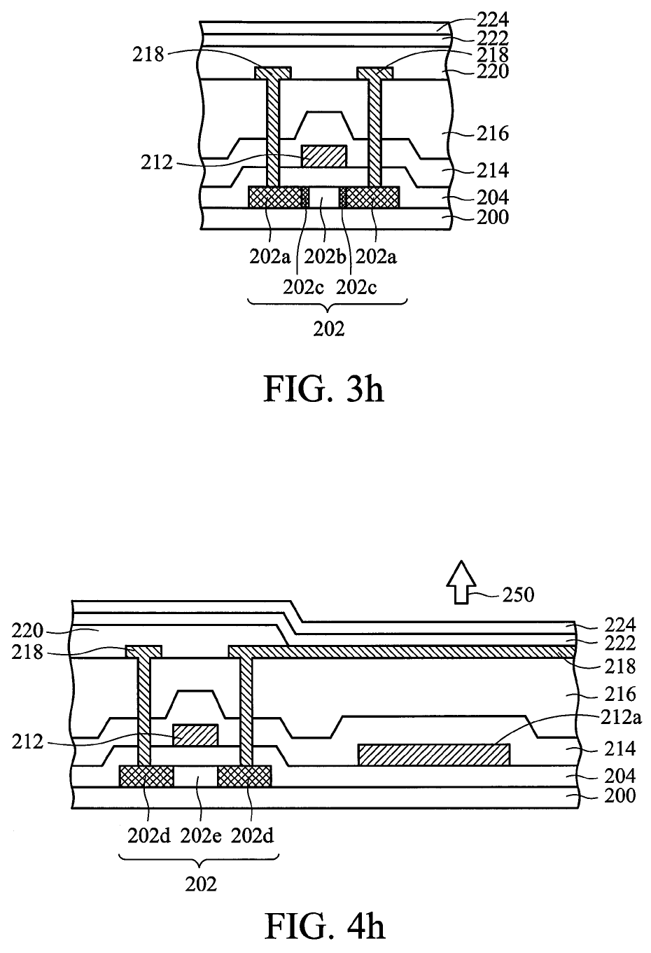

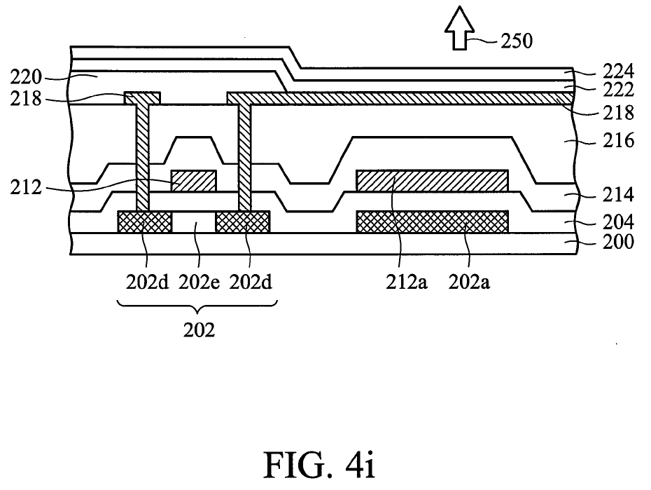

FIGS. 3a-3h and FIGS. 4a-4h illustrate cross sections taken along line 3-3 in region T1 and line 4-4 in region T2 of FIG. 2, respectively, illustrating process steps for fabricating display pixels of the electroluminescent device according to the invention.

Herein, the TFT formed in the region T1 is illustrated as an N-type TFT and the TFT formed in the region T2 is illustrated as a P-type TFT for example only and are not limited thereto. For example, both of the TFTs formed in the regions T1 and T2 can be P-type TFTs or N-type TFTs, or the TFT formed in the region T1 can be a P-type TFT and the TFT formed in the region T2 can be an N-type TFT.

Referring now to FIGS. 3a and 4a, a substrate 200, for example a transparent glass or plastic substrate, is first provided. The transparent plastic substrate may comprise polyelthyleneterephthalate, polyester, polycarbonates, polyacrylates, or polystyrene. Next, an active layer, for example a polysilicon or amorphous silicon layer, is formed on the substrate 200 and patterned by sequential photolithography and etching processes (neither process is shown) through the use of a first reticle (not shown) having predetermined patterns thereon, thereby forming an active layer 202 on the substrate 200 in regions T1 and T2 and covering a portion thereof.

Referring now to FIGS. 3b and 4b, a dielectric layer 204 is next blanketly formed over the structure illustrated in FIGS. 3a and 4a. The dielectric layer 204 can be, for example, a silicon dioxide layer covering the active layers 202 formed on the substrate 200. Next, a photoresist layer (not shown) is blanketly formed and patterned by sequential photolithography and development processes (both not shown) through the use of a second reticle (not shown) having predetermined patterns thereon, thereby forming a patterned photoresist layer 206 in each of the regions T1 and T2, wherein the resist layer 206 formed in the region T1 partially covers the underlying active layer 202 and the resist layer 206 formed in the region T2 entirely covers the underlying active layer 206. Next, an ion implantation process (not shown) is performed, incorporating N type ions such as arsenic or phosphorus and using the photoresist layer 206 as an implant mask, thereby forming a pair of source/regions 202a in the active layer 202 not covered by the photoresist layer 206 in the region T1 and thereby defining a channel region 202b therebetween.

Referring now to FIGS. 3c and 4c, after removal of the photoresist layers 206 illustrated in FIGS. 3b and 4b, another photoresist layer (not shown) is next blanketly formed and patterned by sequential photolithography and development processes (neither process is shown) through the use of a third reticle (not shown) having predetermined patterns thereon, thereby forming a patterned photoresist layer 208 in each of the regions T1 and T2, wherein the resist layer 208 formed in the region T2 entirely covers the underlying active layer 202 and the resist layer 208 formed in the region T1 partially covers the underlying active layer 102 to thereby expose portions of the channel region 202b. Next, an ion implantation process (not shown) is performed, implanting N type ions such as arsenic or phosphorus and using the photoresist layers 208 as implant masks, thereby forming a pair of lightly doped source/regions 202c adjacent to the source/drain regions 202a in the active layer 202 not covered by the photoresist layer 208 of the region T1. The doping concentrations of the lightly doped source/regions 202c are less than that of the source/regions 202a.

Referring now to FIGS. 3d and 4d, after removal the resist layers 208 illustrated in FIGS. 3c and 4c, another photoresist layer (not shown) is next blanketly formed over the dielectric layer 204 and patterned by sequential photolithography and development processes (neither process is shown) through the use of a fourth reticle having predetermined patterns thereon, thereby forming a patterned photoresist layer 210 in each of the regions T1 and T2. As shown in FIGS. 3d and 4d, the resist layer 210 formed in the region T1 entirely covers the underlying active layer 102 and the resist layer 210 formed in the region T2 partially covers the underlying active layer 202. Next, an ion implantation process (not shown) is performed, incorporating P-type ions such as boron and using the photoresist layers 210 as implant masks, thereby forming a pair of doped source/regions 202d in the active layer 202 not covered by the photoresist layer 210 of the region T2 and defining a channel region 202e therebetween.

Referring now to FIGS. 3e and 4e, after removal of the resist layers 210 illustrated in FIGS. 3d and 4d, a metal layer 212 is blanketly formed over the substrate 200. The metal layer 212 may comprise Al, Ti, Ta, Cr, Mo or combinations thereof. The metal layer 212 is then patterned by sequential photolithography and etching processes (neither process is shown) through the use of a fifth reticle (not shown) having predetermined patterns thereon, thereby forming a patterned metal layer 212 in each of the regions T1 and T2, wherein the metal layers 210 substantially overlies a channel region 202e, 202b in the regions T1 and T2, respectively. It is noted that another metal layer 212a is simultaneously formed and covers portions of the dielectric layer 204 not covered by the active layer 202, thereby functioning as a bottom electrode of a capacitor. So far, a P-type TFT and an N-type TFT are substantially formed over the substrate 200 in the regions T1 and T2, respectively.

Referring now to FIGS. 3f and 4f, an inter-layer dielectric layer 214 is next conformably formed over the substrate 200, covering the metal layer 212 and the dielectric layer 204 and insulates the metal layers 212 and 212a. Next, an optional planarization layer 216 is blanketly formed over the substrate 200 by a method such as spin-coating to thereby planarize the surface. Herein, the planarization layer 216 may comprise polyimide, polyacrylate, or silicon-containing polymers. Next, the planarization layer 216 is then patterned by sequential photolithography and etching processes (neither process is shown) through the use of a sixth reticle (not shown) having predetermined patterns thereon, thereby forming two openings OP in each of the regions T1 and T2, respectively. The openings OP are formed through the planarization layer 216, the inter-layer dielectric layer 214 and the dielectric layer 204, respectively revealing portions of the source/drain regions 202a and 202d in the regions T1 and T2.

Referring now to FIGS. 3g and 4g, a conductive layer is blanketly formed over the substrate 200 and fills the openings OP. Next, the conductive layer is patterned by sequential photolithography and etching processes (neither process is shown) through the use of a seventh reticle (not shown) having predetermined patterns thereon, thereby forming a patterned conductive layer 218 in each of the regions T1 and T2, respectively connecting the source/drain regions 202a, 202d in the regions T1 and T2. Herein, the conductive layer 218 may comprise indium oxide such as indium tin oxide (ITO) or indium zinc oxide (IZO), metal of II group (e.g. Ca, Mg) and III group (e.g. Al).

Referring now to FIGS. 3h and 4h, a cap layer 220 is next blanketly formed over the substrate 200 to planarize the surface of the device. The cap layer 220 may comprise polyimide, polyacrylate, silicon-containing polymer, SiOx, SiNx or the like. Next, the cap layer 220 is patterned by sequential photolithography and etching processes (both not shown) through the use of a eighth reticle (not shown) having predetermined patterns thereon, thereby removing portions of the cap layer in the region T2 and exposing portions of the conductive layer 218 therein and defining a region for forming display element. Next, a light-emitting layer 222 and a conductive layer 218 are sequentially formed over the conductive layer 218, thereby forming an AM electroluminescent device. Herein, the light-emitting layer 222 can be an organic light-emitting layer comprising organic light-emitting diode materials. The light-emitting layer 222 may comprise sub-layers such as hole-injecting layer, organic light-emitting layer and electron ejecting layer but is merely illustrated as a single light-emitting layer 222 here. The conductive layer 218 may, for example, comprise Ca, Ag, Mg, Al, Li or other metal materials and can be formed by methods such as vacuum vapor evaporation and sputtering. The conductive layer 224 may comprise transparent conductive materials such as ITO, IZO, AZO or ZnO. The electroluminescent device illustrated in FIG. 4h is a top-emission display device with a light-emitting direction 250 toward a direction away from the substrate 200. The conducive layer 218 formed in the display region functions as a bottom electrode and a storage capacitor is thus formed, including the conducive layer 218, the metal layer 212a and, the planarization layer 214 and inter-layer dielectric layer 214 formed therebetween.

Alternatively, as shown in FIG. 4i, an additional active layer 202a can be formed on a portion of the substrate 200 in the region T2 during formation of the active layer 202 and is doped by ions of the proper type in the sequential processes. The active layer 202a is illustrated as P-type doped layer herein and is substantially located under the metal layer 202a and is isolated by a dielectric layer 204 therebetween. Therefore, a top emission display device with a limiting direction 250 as illustrated in FIG. 4i is formed. Herein, the conductive layer 218, the conductive layer 212a, the active layer 202a and the dielectric layer 204, the inter-layer dielectric layer 214 and the planarization layer 216 forms the storage capacitor.

Through illustration of the above figures, fabrication of TFTs in such a device requires the use of four to five reticles and fabrication of the AM electroluminescent device requires use of only eight reticles. In this embodiment, through integrating fabrication of the source/drain contact with the electrode layer for the AM electroluminescent device in a common reticle and forming source/drain contacts after formation of the planarization layer, the entire number of fabrication steps can be reduced. Thus, compared with the conventional method, the number of reticles used is reduced by two, thereby enhancing fabrication efficiency and reducing costs.

### Second Embodiment

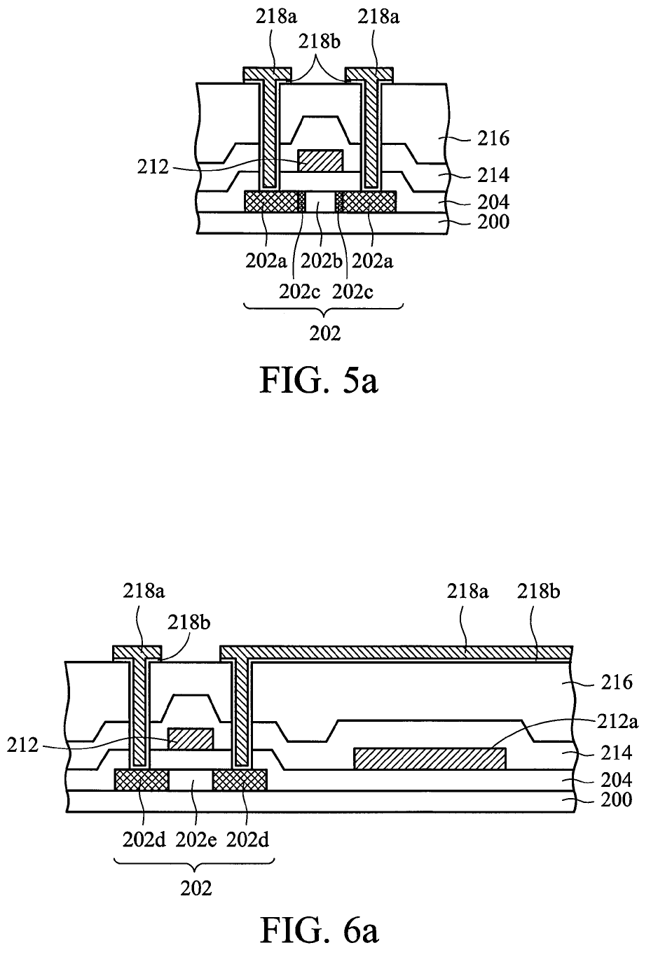

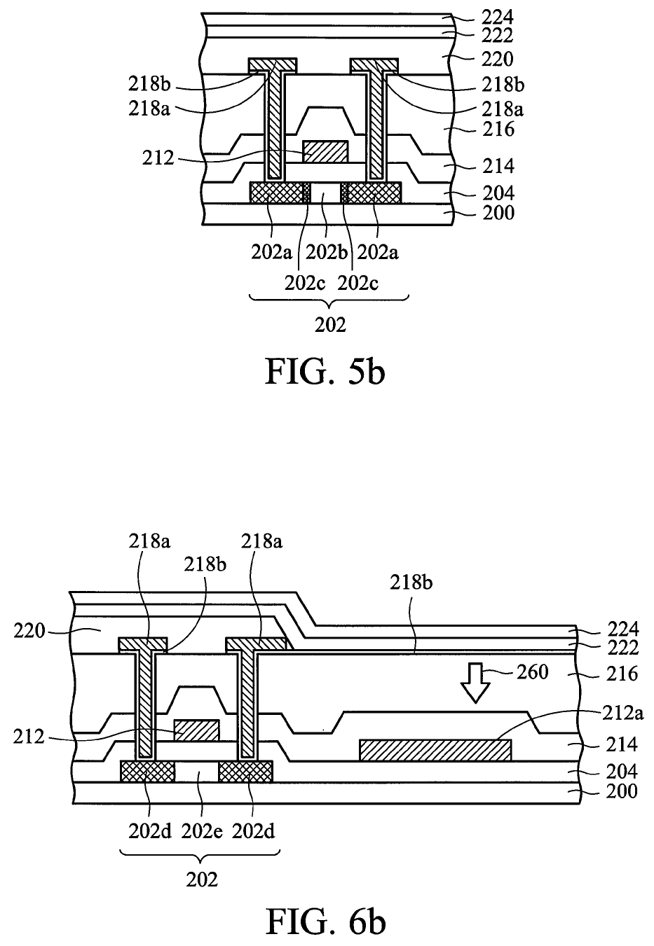

FIGS. 5a-5b and FIGS. 6a-6b illustrate cross sections taken along line 3-3 in the region T1 and line 4-4 in the region T2 of FIG. 2, respectively, illustrating process steps for fabricating display pixels of the electroluminescent device according to another embodiment of the invention. The process illustrated in the second embodiment is similar to that illustrated in the first embodiment and only differences therebetween are described in detail in the following. In this embodiment, a bottom-emission AM electroluminescent device is provided.

Referring now to FIGS. 5a and 6a, the structure illustrated in FIGS. 3f and 4f formed by fabrication steps illustrated through FIGS. 3a-3f and 4a-4f are first provided. Next, a conductive layer is first conformably formed over the structures illustrated in FIGS. 3f and 4f and another conductive layer is then blanketly formed over the previous conductive layer and fills the openings illustrated in FIGS. 3f and 4f. Next, the above conductive layers are patterned by sequential photolithography and etching processes (neither process is shown) through the use of a seventh reticle (not shown) having predetermined patterns thereon, thereby forming a patterned conductive layer comprising sub-layers 218a and 218b in each of the regions T1 and T2, respectively connecting the source/drain regions 202a, 202d in the regions T1 and T2. Herein, the conductive layer 218a may comprise metal and the conductive layer 218b may comprise transparent conductive materials such as indium oxide such as indium tin oxide (ITO) or indium zinc oxide (IZO).

Referring now to FIG. 5b and 6b, a cap layer 220 is next blanketly formed over the substrate 200 to planarize the surface of the device. The cap layer 220 is then patterned by sequential photolithography and etching processes (neither process is shown) through the use of a eighth reticle (not shown) having predetermined patterns thereon, thereby removing portions of the cap layer 220 and the conductive layer 218a in the region T2 and exposing portions of the conductive layer 218b therein and defining a region for forming display element. Next, a light-emitting layer 222 and a conductive layer 218 are sequentially formed over the conductive layer 218, thereby forming an AM electroluminescent device of this embodiment. Herein, since the conductive layer 218b is a transparent conductive layer and the conductive layer 224 is an opaque conductive layer, the electroluminescent device illustrated in FIG. 6b is formed as a bottom-emission display device having a light-emitting direction 260 toward the substrate 200. The conducive layer 218b formed in the display region functions as a bottom electrode and a storage capacitor is thus formed, including the conducive layer 218b, the metal layer 212a and, the planarazition layer 214 and inter-layer dielectric layer 214 formed therebetween.

Through illustration of the above figures, fabrication of TFTs in such a device requires the use of five reticles and fabrication of the AM electroluminescent device requires use of only eight reticles. In this embodiment, through integrating fabrication of the source/drain contact with the electrode layer for the AM electroluminescent device in a common reticle and forming source/drain contacts after formation of the planarizaiton layer, the number of fabrication steps can be reduced. Thus, compared with the conventional method, the number of reticles used is reduced by two, thereby enhancing fabrication efficiency and reducingcosts.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electroluminescent device, comprising
a substrate;
a thin film transistor (TFT) formed on the substrate;
an insulating layer overlying the TFT;
an opening formed in the insulating layer, exposing a source/drain region of the TFT;
a conductive layer formed over a portion of the insulating layer, filling the opening;
a protection layer overlying a portion of the insulating layer and the conductive layer;
a light-emitting layer overlying a portion of the conductive layer not covered by the protection layer; and
a top electrode overlying the light-emitting layer.

2. The electroluminescent device as claimed in claim 1, wherein the portion of the conductive layer not covered by the conducting layer functions as a bottom electrode.

3. The electroluminescent device as claimed in claim 1, wherein the light-emitting layer comprises organic materials.

4. The electroluminescent device as claimed in claim 1, wherein the electroluminescent device emits light toward a direction away from the substrate.

5. An electroluminescent device, comprising
a substrate;
a thin film transistor (TFT) formed on the substrate;
an insulation layer overlying the TFT and the substrate;
an opening formed in the insulating layer, exposing a source/drain region of the TFT;
a transparent conductive layer conformably formed over the insulating layer and in the opening;
an opaque conductive layer overlying a portion of the transparent conductive layer;
a protection layer overlying the opaque conductive layer and the transparent conductive layer, exposing a portion of the transparent conductive layer;
a light-emitting layer overlying the portion of the transparent conductive layer exposed by the protection layer; and
a top electrode overlying the light-emitting layer.

6. The electroluminescent device as claimed in claim 5, wherein the portion of the transparent conductive layer not covered by the protection layer functions as a bottom electrode.

7. The electroluminescent device as claimed in claim 5, wherein the light-emitting layer comprises organic materials.

8. The electroluminescent device as claimed in claim 5, wherein the electroluminescent device emits light toward the substrate.

9. A method for fabricating an electroluminescent device, comprising
providing a substrate;
forming a first thin film transistor (TFT) and a second thin film transistor (TFT) on the substrate, wherein the first and second TFTs comprises different conductivities;
forming an insulating layer, covering the first and second TFTs and the substrate;
forming a plurality of openings in the insulating layer, respectively exposing a pair of source/drain regions of the first and second TFTs;
forming a conductive layer over a portion of the insulating layer, filling the openings and covering portions of the insulating layer adjacent thereto;
forming a protection layer over the conductive layer, exposing a portion of the conductive layer adjacent to the first TFT;
forming a light-emitting layer over the protection layer and the portion of the conductive layer exposed by the protection layer; and
forming a top electrode overlying the light-emitting layer.

10. The method as claimed in claim 9, wherein the first TFT is a P-type transistor and the second TFT is an N-type transistor.

11. The method as claimed in claim 9, wherein the portion of the conductive layer exposed by the protection layer functions as a bottom electrode.

12. The method as claimed in claim 9, wherein the light-emitting layer comprises organic materials.

13. The method as claimed in claim 9, wherein the electroluminescent device emits light toward a direction away from the substrate.

14. The method as claimed in claim 9, wherein the conductive layer comprises opaque conductive materials.

15. The method as claimed in claim 9, further comprising a step of forming an opaque conductive layer over the conductive layer exposed by the protection layer and the conductive layer comprises transparent conductive materials.

16. The method as claimed in claim 15, wherein the electroluminescent device emits light toward the substrate.

17. A method for fabricating an electroluminescent device, comprising
providing a substrate;
forming a thin film transistor (TFT) on the substrate;
forming an insulating layer, covering the TFTs and the substrate;
forming a plurality of openings in the insulating layer, respectively exposing a pair of source/drain regions of the TFT;
forming a conductive layer over a portion of the insulating layer, filling the openings and covering portions of the insulating layer adjacent thereto;
forming a protection layer over the conductive layer, exposing a portion of the conductive layer adjacent to the TFT;
forming a light-emitting layer over the portion of the conductive layer exposed by the protection layer; and
forming a top electrode overlying the light-emitting layer.

18. The method as claimed in claim 17, wherein the TFT is a P-type transistor.

19. The method as claimed in claim 17, wherein the portion of the conductive layer exposed by the protection layer functions as a bottom electrode.

20. The method as claimed in claim 17, wherein the light-emitting layer comprises organic materials.

21. The method as claimed in claim 17, wherein the electroluminescent device emits light toward a direction away from the substrate.

22. The method as claimed in claim 17, wherein the conductive layer comprises opaque conductive materials.

23. The method as claimed in claim 17, further comprising a step of forming an opaque conductive layer over the conducting layer exposed by the protection layer and the conductive layer comprises transparent conductive materials.

24. The method as claimed in claim 15, wherein the electroluminescent device emits light toward the substrate.
